(19) United States
(12) Patent Application Publication
(10) Pub. No.: US 2020/0286936 A1
(43) Pub. Date: Sep. 10, 2020

(54) SEMICONDUCTOR DEVICE AND MANUFACTURING METHOD OF SEMICONDUCTOR DEVICE

(71) Applicant: SONY SEMICONDUCTOR SOLUTIONS CORPORATION, KANAGAWA (JP)

(72) Inventor: TAKAYUKI ENOMOTO, KUMAMOTO (JP)

(21) Appl. No.: 16/765,306

(22) PCT Filed: Oct. 15, 2018
(86) PCT No.: PCT/JP2018/038287

§ 371 Date: May 19, 2020

(30) Foreign Application Priority Data
Nov. 28, 2017 (JP) 2017-227373

(51) Int. Cl. H01L 27/146; H01L 21/762; H01L 29/06

(52) U.S. Cl. CPC H01L 27/1463; H01L 29/063; H01L 21/76224

(57) ABSTRACT

The present technology reduces influence of a crystal defect which has occurred on a semiconductor substrate in the vicinity of an element isolation region. A semiconductor device includes a semiconductor element region, an element isolation region and a high-concentration impurity region. The semiconductor element region is disposed on a surface of the semiconductor substrate. An element isolation region is formed in a predetermined depth from the surface of the semiconductor substrate and isolates the semiconductor element region. The high-concentration impurity region is constituted to have impurity concentration higher than impurity concentration of the semiconductor substrate, is disposed between the semiconductor element region and the element isolation region, and is not disposed below the element isolation region.

### TECHNICAL FIELD

The present technology relates to a semiconductor device and a manufacturing method of a semiconductor device. More particularly, the present technology relates to a semiconductor device including an element isolation region which isolates a region where a semiconductor element is formed, and a manufacturing method of the semiconductor device.

### BACKGROUND ART

In related art, a semiconductor device in which a plurality of elements is formed on one semiconductor substrate, and element isolation regions which isolate these elements are disposed, has been used. For example, in an imaging element in which pixels which perform photoelectric conversion in accordance with incident light and generate analog image signals are arranged in a two-dimensional grid shape, an imaging element in which element isolation regions are disposed between respective pixels is used. In this imaging element, to prevent occurrence of an error in an image signal due to inflow of a leak current generated in association with photoelectric conversion at a pixel, to another pixel, element isolation regions are disposed between the pixels.

As such a semiconductor device, for example, an imaging device in which an element isolation region which isolates an active element dealing with an electric charge generated by photoelectric conversion from another active element, is disposed within a pixel, has been proposed. This imaging device includes an element isolation region constituted with an insulating film of silicon oxide, or the like, a first impurity region surrounding this element isolation region, and a second impurity region which is disposed between the first impurity region and an active element, and which has impurity concentration lower than that in the first impurity region (see, for example, Patent Document 1).

The above-described imaging device suppresses inflow of a leak current based on a crystal defect at an interface of the element isolation region, to the active element, with the first and the second impurity regions. Further, by the second impurity region of which impurity concentration is lower being disposed between the first impurity region and the active element, a gradient of impurity concentration between the element isolation region and the active element is reduced, so that electric field intensity is lowered, and inflow of a leak current to the active element is suppressed.

### CITATION LIST

### Patent Document

Patent Document 1: Japanese Patent Application Laid-Open No. 2010-212319

### SUMMARY OF THE INVENTION

### Problems to be Solved by the Invention

At an interface of a semiconductor substrate on which an element isolation region is formed, a crystal defect such as displacement due to stress occurs, and extends. A leak current increases due to this extending crystal defect. With the above-described related art, there is a problem that it is impossible to prevent increase in a leak current due to an extending crystal defect.

The present technology has been made in view of the above-described problem, and is directed to reducing influence on a semiconductor element region based on a crystal defect which has occurred on a semiconductor substrate in the vicinity of an element isolation region.

### Solutions to Problems

The present technology is provided in order to solve the above-mentioned issues, and according to a first aspect of the present technology, there is provided a semiconductor device including a semiconductor element region disposed on a surface of a semiconductor substrate, an element isolation region which is formed in a predetermined depth from the surface of the semiconductor substrate and which isolates the semiconductor element region, and a high-concentration impurity region which is constituted to have impurity concentration higher than impurity concentration of the semiconductor substrate, which is disposed between the semiconductor element region and the element isolation region, and which is not disposed below the element isolation region. By this means, action is provided that the high-concentration impurity region is disposed between the element isolation region and the semiconductor element region, and the high-concentration impurity region is not disposed between a bottom portion of the element isolation region and the semiconductor substrate. Due to concentration of stress, a crystal defect such as displacement occurs on the semiconductor substrate in the vicinity of the element isolation region, and extends to a surrounding semiconductor substrate. Suppression of extension of the crystal defect below the element isolation region by the high-concentration impurity region being not disposed below the element isolation region, and suppression of extension of the crystal defect to the semiconductor element region by the high-concentration impurity region being disposed between the element isolation region and the semiconductor element region, are expected.

Further, in this first aspect, the above-mentioned element isolation region may be constituted with an insulator. By this means, action that the semiconductor element region is isolated by an insulator, is provided.

Further, in this first aspect, the above-mentioned high-concentration impurity region may be formed in a region deeper than a bottom portion of the element isolation region from a surface of the semiconductor element. By this means, action is provided that the high-concentration impurity region which is formed to a region deeper than the bottom portion of the element isolation region from the surface of the semiconductor substrate is disposed between the semiconductor element region and the element isolation region.

Further, in this first aspect, the above-mentioned element isolation region may include a bottom portion having a cross-section in a tapered shape of which width becomes narrower as a depth from the surface of the semiconductor substrate becomes deeper. By this means, action is provided that the bottom portion of the element isolation region is constituted in a tapered shape. Concentration of stress to a top of the tapered shape at the bottom portion is expected.

Further, in this first aspect, the above-mentioned element isolation region may have an angle based on a cross-section at a portion which transitions to the bottom portion in the tapered shape, greater than an angle based on a cross-section at a top of the tapered shape. By this means, action is provided that change in a width of a cross-section of the element isolation region is larger at a portion in the vicinity of the top of the tapered shape than that at a portion where the shape is transitioning to the tapered shape. Concentration of stress at the bottom portion of the element isolation region to the vicinity of the top of the tapered shape is expected.

Further, according to a second aspect of the present technology, there is provided a manufacturing method of a semiconductor device, including a step of forming a semiconductor element region on a surface of a semiconductor substrate, a step of forming an element isolation region which isolates the semiconductor element region in a predetermined depth from the surface of the semiconductor substrate, and a step of forming a high-concentration impurity region having impurity concentration higher than impurity concentration of the semiconductor substrate, between the semiconductor element region and the element isolation region, while not forming the high-concentration impurity region below the element isolation region. By this means, action is provided that the high-concentration impurity region is disposed between the element isolation region and the semiconductor element region, and the high-concentration impurity region is not disposed between a bottom portion of the element isolation region and the semiconductor substrate. Suppression of extension of the crystal defect below the element isolation region by the high-concentration impurity region being not disposed below the element isolation region, and suppression of extension of the crystal defect to the semiconductor element region by the high-concentration impurity region being disposed between the element isolation region and the semiconductor element region, are expected.

### Effects of the Invention

According to the present technology, in a case where a crystal defect which has occurred between an element isolation region and a semiconductor substrate extends, an excellent effect that influence of the crystal defect on a semiconductor element region is reduced is provided.

### BRIEF DESCRIPTION OF DRAWINGS

FIG. 1 is a diagram illustrating a configuration example of an imaging element according to an embodiment of the present technology.

FIG. 2 is a diagram illustrating a configuration example of a pixel according to an embodiment of the present technology.

FIG. 3 is a diagram illustrating a disposition example of the pixels according to an embodiment of the present technology.

FIG. 4 is a diagram illustrating a configuration example of a pixel array unit according to a first embodiment of the present technology.

FIG. 5 is a diagram illustrating a configuration example of an element isolation region and a high-concentration impurity region according to the first embodiment of the present technology.

FIG. 6 is a diagram illustrating an example of a manufacturing method of the element isolation region and the high-concentration impurity region according to the first embodiment of the present technology.

FIG. 7 is a diagram illustrating an example of a manufacturing method of the element isolation region and the high-concentration impurity region according to the first embodiment of the present technology.

FIG. 8 is a diagram illustrating a configuration example of an element isolation region and a high-concentration impurity region according to a modified example of the first embodiment of the present technology.

FIG. 9 is a diagram illustrating a configuration example of an element isolation region and a high-concentration impurity region according to a second embodiment of the present technology.

FIG. 10 is a diagram illustrating an example of a manufacturing method of the element isolation region and the high-concentration impurity region according to the second embodiment of the present technology.

FIG. 11 is a diagram illustrating a configuration example of an element isolation region and a high-concentration impurity region according to a modified example of the second embodiment of the present technology.

FIG. 12 is a diagram illustrating a configuration example of a pixel array unit according to a third embodiment of the present technology.

FIG. 13 is a diagram illustrating a configuration example of a pixel array unit according to a fourth embodiment of the present technology.

FIG. 14 is a cross-sectional diagram illustrating a first configuration example of an imaging element to which the present technology can be applied.

FIG. 15 is a cross-sectional diagram illustrating a second configuration example of an imaging element to which the present technology can be applied.

FIG. 16 is a cross-sectional diagram illustrating a third configuration example of an imaging element to which the present technology can be applied.

FIG. 17 is a block diagram illustrating a schematic configuration example of a camera that is an example of an imaging device to which the present technology is able to be applied.

FIG. 18 is a view depicting an example of a schematic configuration of an endoscopic surgery system.

FIG. 19 is a block diagram depicting an example of a functional configuration of a camera head and a camera control unit (CCU).

FIG. 20 is a block diagram depicting an example of schematic configuration of a vehicle control system.

FIG. 21 is a diagram of assistance in explaining an example of installation positions of an outside-vehicle information detecting section and an imaging unit.

### MODE FOR CARRYING OUT THE INVENTION

Next, a mode for implementing the present technology (hereinafter referred to as an embodiment) will be described with reference to the drawings. In the following drawings, the same or similar reference signs are attached to the same or similar portions. However, the drawings are schematic, and ratios of dimensions of each unit and the like do not necessarily match the actual ones. In addition, of course, the drawings also include portions having different dimensional relationships and ratios. In addition, the description of the embodiments will be given in the following sequence.

1. First embodiment

2. Second embodiment

3. Third embodiment

4. Fourth embodiment

5. Application example to imaging element

6. Application example to camera system

7. Application example to endoscopic surgery system

8. Application example to mobile object

### <1. First Embodiment>

### [Configuration of Imaging Element]

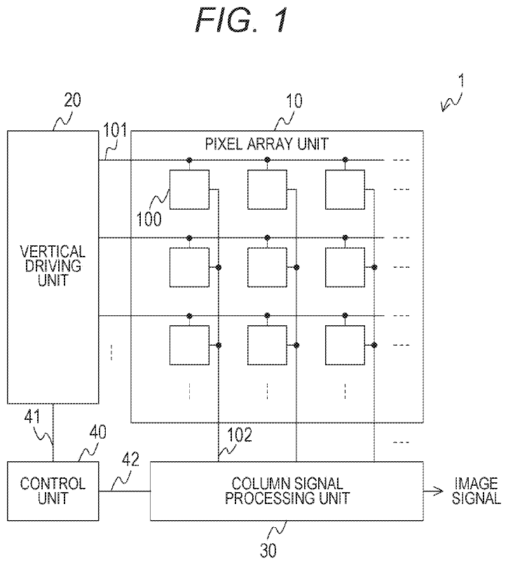

FIG. 1 is a diagram illustrating a configuration example of an imaging element according to an embodiment of the present technology. A semiconductor device according to the embodiment of the present technology will be described with reference to the imaging element 1 in FIG. 1 as an example. The imaging element 1 in FIG. 1 includes a pixel array unit 10, a vertical driving unit 20, a column signal processing unit 30, and a control unit 40.

The pixel array unit 10 is configured by disposing pixels 100 in a two-dimensional grid pattern. Here, each pixel 100 generates an image signal according to irradiated light. The pixel 100 has a photoelectric conversion unit that generates an electric charge according to the irradiated light. In addition, the pixel 100 further includes a pixel circuit. The pixel circuit generates an image signal based on the electric charge generated by the photoelectric conversion unit. The pixel circuit includes an electric charge holding unit which holds the electric charge generated through photoelectric conversion, an image signal generating unit which generates an image signal in accordance with the electric charge held at the electric charge holding unit, and a transferring unit which transfers the electric charge generated by the photoelectric conversion unit to the electric charge holding unit.

The generation of the image signal is controlled by a control signal generated by the vertical driving unit 20 that will be described later. In the pixel array unit 10, signal lines 101 and 102 are disposed in an XY matrix pattern. The signal line 101 is a signal line that transfers the control signal of the pixel circuit in the pixel 100, and the signal line 101 is disposed for each row of the pixel array unit 10, and is wired in common to the pixels 100 disposed in each row. The signal line 102 is a signal line that transfers the image signal generated by the pixel circuit of the pixel 100, and the signal line 102 is disposed for each column of the pixel array unit 10 and is wired in common to the pixels 100 disposed in each column. The photoelectric conversion unit and the pixel circuit are formed on a semiconductor substrate.

The vertical driving unit 20 generates the control signal of the pixel circuit of the pixel 100. The vertical driving unit 20 transfers the generated control signal to the pixel 100 through the signal line 101 in FIG. 1. The column signal processing unit 30 processes the image signal generated by the pixel 100. The column signal processing unit 30 performs a process of the image signal transferred from the pixel 100 through the signal line 102 in FIG. 1. The process in the column signal processing unit 30 corresponds to, for example, analog-to-digital conversion for converting an analog image signal generated in the pixel 100 into a digital image signal. The image signal processed by the column signal processing unit 30 is output as the image signal of the imaging element 1. The control unit 40 controls the entire imaging element 1. The control unit 40 controls the imaging element 1 by generating and outputting the control signal for controlling the vertical driving unit 20 and the column signal processing unit 30. The control signals generated by the control unit 40 are transmitted to the vertical driving unit 20 and the column signal processing unit 30 through signal lines 41 and 42, respectively.

In such an imaging element 1, an element isolation region which electrically isolates electrical circuits and functional blocks having different characteristics is disposed. For example, while the vertical driving unit 20, the column signal processing unit 30 and the control unit 40 in FIG. 1 mainly deal with high-speed digital signals, the pixel array unit 10 deals with analog image signals. Further, compared to the vertical driving unit 20, or the like, a power supply of a high voltage is applied to the pixel array unit 10. In this manner, characteristics of electrical circuits at which the vertical driving unit 20, or the like, are disposed, are different from characteristics of an electrical circuit at which the pixel array unit 10 is disposed. Therefore, by forming an element isolation region between the vertical driving unit 20, or the like, and the pixel array unit 10 having different such characteristics, and electrically isolating them from each other, it is possible to prevent noise contamination, or the like. Further, there is a case where, at the pixel array unit 10, a current based on an electric charge which has occurred through photoelectric conversion at the pixel 100 and a leak current based on the power supply voltage applied to the pixel 100 flow into an adjacent pixel 100. This inflow current is referred to as a dark current, and becomes a cause of an error in an image signal. To reduce such a dark current, it is also possible to dispose an element isolation region between the pixels 100. Note that the imaging element 1 is an example of a semiconductor device recited in the claims.

### [Configuration of Pixel]

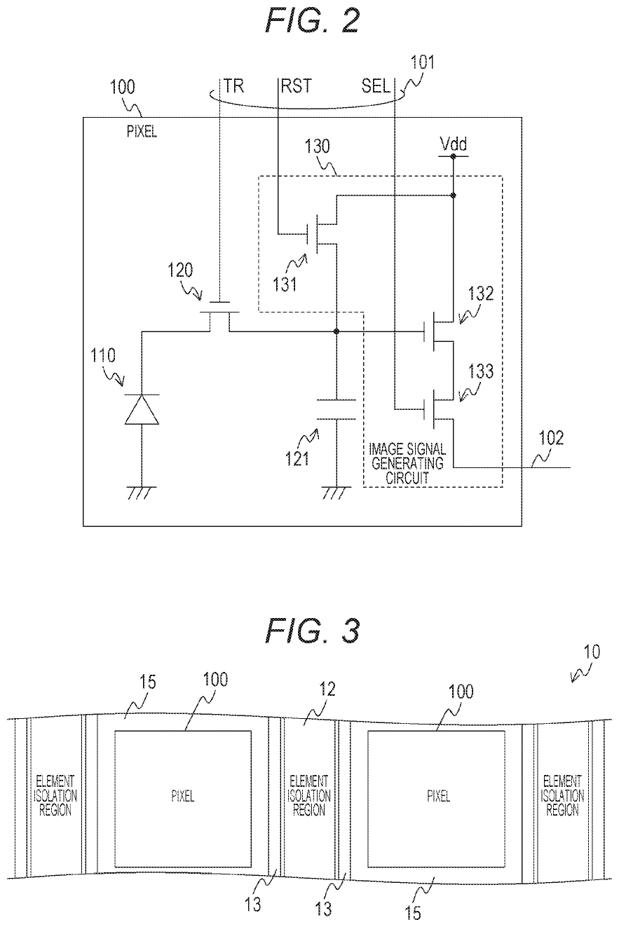

FIG. 2 is a diagram illustrating a configuration example of a pixel according to an embodiment of the present technology. FIG. 2 is a circuit diagram illustrating a configuration example of the pixel 100. The pixel 100 in FIG. 2 includes a photoelectric conversion unit 110, an electric charge holding unit 121, and MOS transistors 120 and 131 to 133.

An anode of the photoelectric conversion unit 110 is grounded, and a cathode is connected to a source of the MOS transistor 120. A drain of the MOS transistor 120 is connected to a source of the MOS transistor 131, a gate of the MOS transistor 132 and one end of the electric charge holding unit 121. The other end of the electric charge holding unit 121 is grounded. Drains of the MOS transistors 131 and 132 are commonly connected to a power supply line Vdd, and a source of the MOS transistor 132 is connected to a drain of the MOS transistor 133. A source of the MOS transistor 133 is connected to a signal line 102. Gates of the MOS transistors 120, 131 and 133 are respectively connected to a transfer signal line TR, a reset signal line RST and a select signal line SEL. Note that the transfer signal line TR, the reset signal line RST and the select signal line SEL constitute a signal line 101. Note that the MOS transistors 131 to 133 constitute an image signal generating circuit 130.

The photoelectric conversion unit 110 generates an electric charge in accordance with radiated light as described above.

As this photoelectric conversion unit 110, a photodiode can be used.

The MOS transistor 120 is a transistor which transfers the electric charge generated through photoelectric conversion by the photoelectric conversion unit 110 to the electric charge holding unit 121. Transfer of the electric charge by the MOS transistor 120 is controlled with a signal transmitted using the transfer signal line TR. The electric charge holding unit 121 is a capacitor which holds the electric charge transferred by the MOS transistor 120. The MOS transistor 132 is a transistor which generates a signal based on the electric charge held by the electric charge holding unit 121. The MOS transistor 133 is a transistor which outputs the signal generated by the MOS transistor 132 to the signal line 102 as an image signal. This MOS transistor 133 is controlled with a signal transmitted using the select signal line SEL.

The MOS transistor 131 is a transistor which resets the electric charge holding unit 121 by discharging the electric charge held by the electric charge holding unit 110 to the power supply line Vdd. This reset by the MOS transistor 131 is controlled with a signal transmitted using the reset signal line RST, and is executed before the electric charge is transferred by the MOS transistor 120. Note that, upon this reset, by putting the MOS transistor 120 into a conduction state, it is also possible to reset the photoelectric conversion unit 110. In this manner, the image signal generating circuit 130 converts the electric charge generated by the photoelectric conversion unit 110 into an image signal.

### [Pixel Arrangement]

FIG. 3 is a diagram illustrating a disposition example of the pixels according to an embodiment of the present technology. FIG. 3 is a diagram illustrating arrangement of the pixels 100 in the pixel array unit 10 described in FIG. 1. At the pixel array unit 10 in FIG. 3, the element isolation regions 12 are disposed between the pixels 100. Further, the high-concentration impurity regions 13 are further disposed between the element isolation regions 12 and the pixels 100.

The element isolation region 12 in FIG. 3 is a region which isolates the above-described adjacent pixels 100. This element isolation region 12 can be constituted with an insulator of, for example, silicon oxide (SiO₂), or the like. As will be described later, the semiconductor element which constitutes the pixel 100 is formed on a surface of a well region 15 formed on the semiconductor substrate. In a similar manner, the element isolation region 12 is also formed on the surface of the well region 15, and isolates the pixels 100 from each other. Here, the well region 15 is a semiconductor region constituted to have predetermined impurity concentration. Semiconductor elements of all the pixels 100 at the pixel array unit 10 are formed within the well region 15.

The high-concentration impurity region 13 is a semiconductor region constituted to have high impurity concentration, and is disposed adjacent to the element isolation region 12. As a result of this high-concentration impurity region 13 being constituted to have high impurity concentration, a crystal defect which has occurred in the semiconductor substrate is prevented from extending to the pixel 100 due to stress at an interface between the element isolation region 12 and the semiconductor substrate. Configurations of the element isolation region 12 and the high-concentration impurity region 13 will be described in detail later. Note that the pixel 100 is an example of a semiconductor element region recited in the claims.

### [Configuration of Pixel Array Unit]

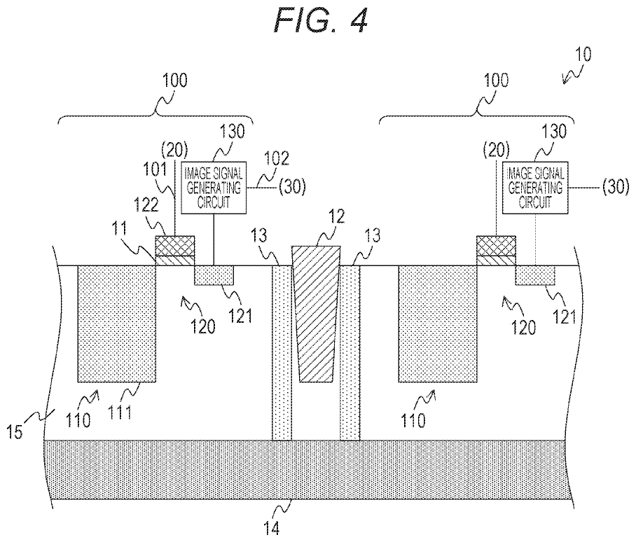

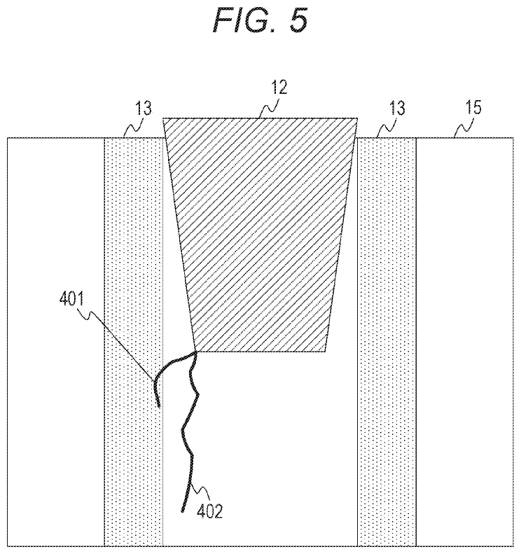

FIG. 4 is a diagram illustrating a configuration example of a pixel array unit according to a first embodiment of the present technology. FIG. 4 is a schematic cross-sectional diagram illustrating a configuration example of the pixel array unit 10. Further, FIG. 4 illustrates two pixels 100, the element isolation region 12 and two high-concentration impurity regions 13. These pixels 100, or the like, are formed within the well region 15 formed on the semiconductor substrate 14. The semiconductor substrate 14 is a substrate formed with silicon (Si), or the like, and is a substrate constituted to have relatively low impurity concentration. The semiconductor substrate 14 in FIG. 4 can be constituted at, for example, an N-type semiconductor. As this semiconductor substrate 14, for example, an epitaxial wafer in which an impurity corresponding to a donor is doped can be used. Impurity concentration of the semiconductor substrate 14 can be set at, for example, 10¹²/cm³. The well region 15 is a semiconductor region formed within the semiconductor substrate 14, and is a region where the semiconductor element of the pixel 100 is to be formed. Further, the well region 15 can be formed by an impurity being introduced to the semiconductor substrate 14, and can be constituted to have impurity concentration higher than that of the semiconductor substrate 14, for example, 10¹³/cm³. The well region 15 can be constituted at, for example, a P-type semiconductor. Note that the semiconductor substrate 14 can be constituted with gallium nitride (GaN), silicon carbide (SiC) and gallium arsenide (GaAs), other than Si.

The pixel 100 in FIG. 4 includes the photoelectric conversion unit 110, the electric charge holding unit 121, the electric charge transferring unit 120, and the image signal generating circuit 130. As will be described later, the photoelectric conversion unit 110 can be constituted with a photodiode. This photodiode is constituted with an N-type semiconductor region 111 formed within the well region 15 and the well region 15 around the N-type semiconductor region 111. Photoelectric conversion is performed at PN junction between the N-type semiconductor region 111 and the well region 15. An electric charge generated through photoelectric conversion is accumulated in the N-type semiconductor region 111. The electric charge holding unit 121 is an N-type semiconductor region formed in the well region 15, and is a region which holds the electric charge generated by the photoelectric conversion unit 110 and accumulated. This electric charge holding unit 121 is constituted to have relatively high impurity concentration, and is constituted to have a potential deeper than that of the N-type semiconductor region 111. This electric charge holding unit 121 is referred to as floating diffusion.

The electric charge transferring unit 120 transfers the electric charge generated by the photoelectric conversion unit 110 to the electric charge holding unit 121. This electric charge transferring unit 120 is a MOS transistor of which source is the N-type semiconductor region 111, of which drain is the electric charge holding unit 121, and of which channel region is the well region 15. Further, a gate 122 is disposed on a surface of the channel region of the electric charge transferring unit 120 via an oxide film 11. The signal line 101 is connected to the gate 122, and a control signal is applied. Further, the image signal generating circuit 130 is connected to the electric charge holding unit 121. This image signal generating circuit 130 generates an image signal in accordance with the electric charge held at the electric charge holding unit 121. The image signal generated by the image signal generating circuit 130 is output to the signal line 102. Further, the image signal generating circuit 130 further performs reset of the electric charge holding unit 121 and the photoelectric conversion unit 110.

The element isolation region 12 is formed to have a predetermined depth from the surface of the well region 15 between the pixels 100. As illustrated in FIG. 4, the semiconductor element such as the pixel 100 is formed on the surface of the well region 15. By forming the element isolation region 12 in the vicinity of the surface of the well region 15, it is possible to insulate the pixels 100 from each other. The element isolation region 12 can be formed, for example, in a region deeper than a region where the semiconductor element constituting the pixel 100 is to be formed. FIG. 4 illustrates an example where the element isolation region 12 is constituted with a shallow trench isolation (STI) in a groove shape. Note that it is also possible to use the element isolation region 12 constituted through local oxidation of silicon (LOCOS).

The high-concentration impurity region 13 is disposed adjacent to both sides of the element isolation region 12, and is formed to penetrate through the well region 15 from the surface to the bottom portion. This high-concentration impurity region 13 can be constituted to have impurity concentration higher than that of the well region 15, for example, have impurity concentration of 10¹⁴ to 10¹⁶/cm³. This impurity concentration can be changed in accordance with impurity concentration in a region around the high-concentration impurity region 13. Further, as an impurity, an impurity corresponding to an accepter or a donor for the semiconductor substrate 14, such as boron (B) , phosphorus (P) and arsenic (As) can be used. Further, it is also possible to use oxygen (O), carbon (C), fluorine (F), or the like, as the impurity.

### [Configuration of High-Concentration Impurity Region]

FIG. 5 is a diagram illustrating a configuration example of an element isolation region and a high-concentration impurity region according to the first embodiment of the present technology. FIG. 5 is a schematic cross-sectional diagram illustrating a configuration of the element isolation region 12 and the high-concentration impurity region 13. The element isolation region 12 has a shape embedded into the semiconductor substrate (well region 15). Further, the element isolation region 12 and the well region 15 are constituted with different materials and have different thermal expansion coefficients. Therefore, stress occurs at an interface between the element isolation region 12 and the well region 15. Distortion occurs in the well region 15 due to this stress, and a crystal defect such as displacement occurs. Particularly, because stress concentrates at a corner portion on a cross-section of the bottom portion of the element isolation region 12, a crystal defect is likely to occur. In FIG. 5, this is expressed with crystal defects 401 and 402. A defect level is formed at such a crystal defect by dangling-bond. By movement of an electric charge with respect to this defect level, a leak current occurs. If such a crystal defect extends to the vicinity of the pixel 100, a leak current based on the crystal defect flows into the pixel 100 and becomes a dark current, which causes an error in an image signal. However, in a case where a crystal defect stays in the vicinity of the element isolation region 12, it is possible to reduce influence of a leak current based on a crystal defect.

Therefore, the high-concentration impurity region 13 is disposed between the pixel 100 and the element isolation region 12, and is disposed in the vicinity of the element isolation region 12. As mentioned above, in the high-concentration impurity region 13, an impurity having concentration higher than that in the well region 15 is introduced. By this high-concentration impurity, it is possible to suppress extension of a crystal defect. This is because, for example, displacement which is a crystal defect is fixed by an impurity. As a result of an impurity aggregating at a tip, or the like, of displacement, the impurity bonds with each other, and it is possible to prevent extension of displacement. By selecting and introducing an impurity which easily aggregates at a displacement portion, it is possible to improve an effect of suppressing extension of a crystal defect. Further, also in a case where extension of displacement is dammed by an impurity, it is possible to suppress extension of a crystal defect.

Further, as illustrated in FIG. 5, the high-concentration impurity region 13 is constituted in a shape which is not disposed below the element isolation region 12. That is, the high-concentration impurity region 13 is not disposed in the well region 15 between the element isolation region 12 and the semiconductor substrate 14. Therefore, the high-concentration impurity region 13 is not constituted in a shape which surrounds the whole of the element isolation region 12 in the well region 15, and has a configuration where the lower portion of the element isolation region 12 is open to the well region 15. Therefore, extension of the crystal defect 401 which is headed to the pixel 100 from the element isolation region 12 is suppressed by the high-concentration impurity region 13. Meanwhile, the crystal defect 402 which is headed downward from the element isolation region 12 extends without being inhibited. By this means, it is possible to confine the crystal defect which has occurred due to stress to the vicinity of the element isolation region 12, so that it is possible to reduce influence of a leak current based on the extending crystal defect.

Further, the high-concentration impurity region 13 can be formed in a region deeper than the bottom portion of the element isolation region 12 from the surface of the well region 15. By this means, it is possible to further block the crystal defect which is headed to the pixel 100 from the element isolation region 12 by the high-concentration impurity region 13. Particularly, it is possible to prevent the crystal defect which has occurred in the vicinity of the bottom portion of the element isolation region 12 from extending to the pixel 100.

### [Manufacturing Method of High-Concentration Impurity Region]

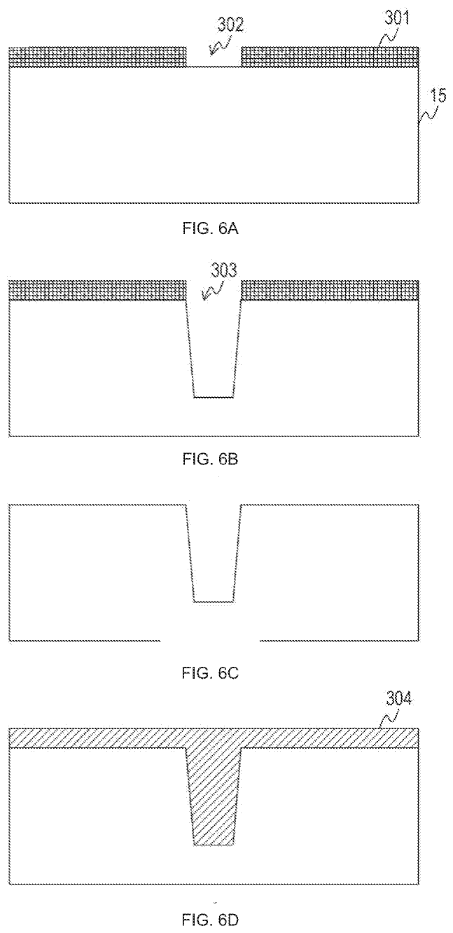

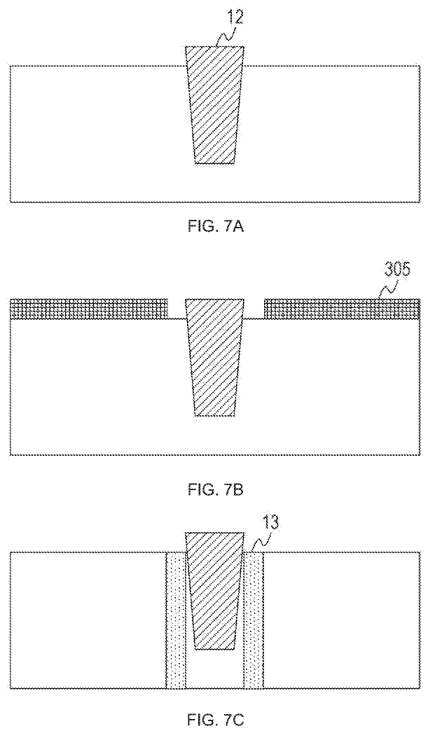

FIGS. 6 and 7 are diagrams illustrating an example of a manufacturing method of the element isolation region and the high-concentration impurity region according to the first embodiment of the present technology. FIGS. 6 and 7 are diagrams illustrating manufacturing process of the element isolation region 12 and the high-concentration impurity region 13. First, the well region 15 is formed on the semiconductor substrate 14, and the semiconductor element of the pixel 100 is formed in this well region 15 (not illustrated). Then, a silicon nitride (SiN) film 301 is formed on a surface of the well region 15. An opening 302 is formed in a region where the element isolation region 12 is to be formed, on this SiN film 301. This opening 302 can be formed by forming a resist on a surface of the SiN film 301, patterning the resist through photolithography, and performing dry etching (a in FIG. 6).

Then, an opening 303 is formed in the well region 15. The opening 303 can be formed by performing dry etching using the SiN film 301 as a hard mask (b in FIG. 6). Then, the SiN film 301 is removed (c in FIG. 6). Then, an SiO₂ film 304 is formed. This can be formed, for example, through chemical vapor deposition (CVD) (d in FIG. 6).

Then, the SiO₂ film 304 formed in a region other than the opening 303 is removed to form the element isolation region 12. The element isolation region 12 can be formed by forming a resist in a region where the element isolation region 12 is to be formed and performing etching (e in FIG. 7). Then, a resist 305 having an opening in a region where the high-concentration impurity region 13 is to be formed, is formed (f in FIG. 7). Then, an impurity is introduced using the resist 305 and the element isolation region 12 as a mask. The impurity can be introduced through ion implantation. Thereafter, the resist 305 is removed (g in FIG. 7). By this means, it is possible to realize a process of forming the high-concentration impurity region 13 adjacent to the element isolation region 12 while not forming the high-concentration impurity region 13 below the element isolation region 12.

Through the process described above, it is possible to form the element isolation region 12 and the high-concentration impurity region 13. Note that it is also possible to use a resist in place of the SiN film 301. Further, it is also possible to use a film on which an SiN film and an SiO₂ film are laminated in place of the SiN film 301. Further, it is also possible to remove the SiO₂ film 304 formed in a region other than the opening 303 through chemical mechanical polishing (CMP).

### MODIFIED EXAMPLE

While the high-concentration impurity region 13 described above penetrates the well region 15 from the surface to the bottom portion, the high-concentration impurity region 13 may be formed in a predetermined depth from the surface of the well region 15.

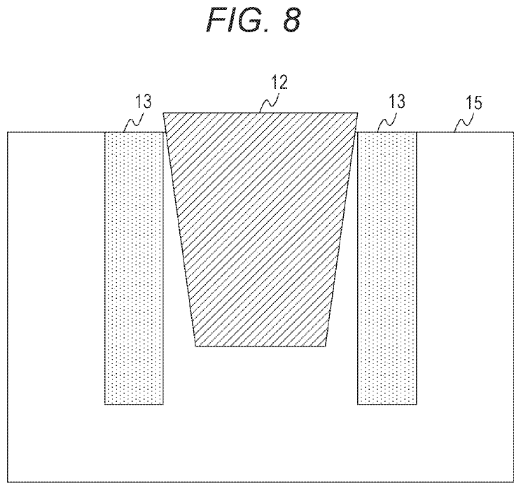

FIG. 8 is a diagram illustrating a configuration example of an element isolation region and a high-concentration impurity region according to a modified example of the first embodiment of the present technology. FIG. 8 is a schematic cross-sectional diagram illustrating a configuration example of the element isolation region and the high-concentration impurity region. In FIG. 8, the high-concentration impurity region 13 is formed in a predetermined depth from the surface of the well region 15. Also in this case, by the high-concentration impurity region 13 being formed in a region deeper than the bottom portion of the element isolation region 12, it is possible to prevent a crystal defect from extending to the vicinity of the pixel 100. By the high-concentration impurity region 13 being constituted in a depth at which the high-concentration impurity region 13 does not penetrate through the well region 15, it is possible to reduce energy for ion implantation when the high-concentration impurity region 13 is formed.

As described above, in the semiconductor device (imaging element 1) in the first embodiment of the present technology, the high-concentration impurity region 13 is disposed between the semiconductor element region (pixel 100) and the element isolation region 12, while the high-concentration impurity region 13 is not disposed below the element isolation region 12. By this means, it is possible to prevent a crystal defect which has occurred in the vicinity of the element isolation region 12 from extending to the vicinity of the semiconductor element region, so that it is possible to reduce influence of the crystal defect on the semiconductor element region.

### <2. Second Embodiment>

The imaging element 1 in the first embodiment described above uses the element isolation region 12 having a flat bottom portion. In contrast, the imaging element 1 in a second embodiment of the present technology is different from the imaging element 1 in the first embodiment in that the element isolation region 12 having a bottom portion in a tapered shape is used.

### [Configuration of High-Concentration Impurity Region]

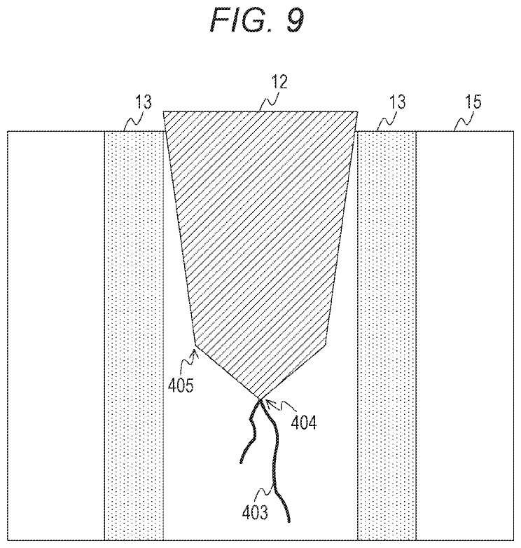

FIG. 9 is a diagram illustrating a configuration example of an element isolation region and a high-concentration impurity region according to a second embodiment of the present technology. FIG. 5 is a schematic cross-sectional diagram illustrating a configuration of the element isolation region 12 and the high-concentration impurity region 13. The element isolation region 12 in FIG. 9 is different from the element isolation region 12 described in FIG. 5 in that the element isolation region 12 has the bottom portion in a tapered shape of which width becomes narrower as a depth from the surface of the well region 15 becomes deeper. By this bottom portion in a tapered shape, the element isolation region 12 has a shape having a convex portion at the bottom portion. Because stress concentrates at a top 404 of such a tapered shape, relatively many crystal defects occur at the top 404. The crystal defect 403 in FIG. 9 indicates this aspect. In this manner, compared to the element isolation region 12 having a flat bottom portion described in FIG. 5, generation of a crystal defect which is headed to the pixel 100 is suppressed. It is possible to reduce a dark current flowing into the pixel 100.

Further, the element isolation region 12 in FIG. 9 has a bottom portion which is formed to have an angle based on a cross-section of a transition portion 405 which is transitioning to the bottom portion in a tapered shape, greater than an angle based on a cross-section of the top 404 of the tapered shape. Therefore, concentration of stress becomes greater at the top 404 than at the transition portion 405. Occurrence of a crystal defect at the transition portion 405 decreases, and generation of a crystal defect which is headed to the pixel 100 is further suppressed. By this means, it is possible to further reduce a leak current flowing into the pixel 100.

### [Manufacturing Method of High-Concentration Impurity Region]

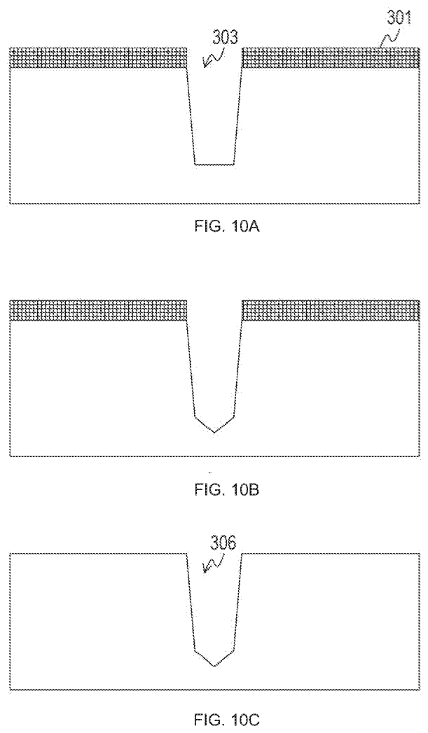

FIG. 10 is a diagram illustrating an example of a manufacturing method of the element isolation region and the high-concentration impurity region according to the second embodiment of the present technology. FIG. 10 is a diagram illustrating a manufacturing process of the element isolation region 12 to be executed in place of the formation process of the opening 306 described in b and c in FIG. 6.

First, the opening 303 described in b in FIG. 6 is formed through dry etching (a in FIG. 10). Then, an etching condition is changed, and dry etching is further performed on the bottom portion of the opening 303. In this event, etching can be performed using the etching condition in which, for example, a flow rate of a gas to be used for etching and power upon generation of plasma are changed, and an adhesion amount of a compound of the gas generated by etching and silicon constituting the well region 15 to a side wall of the opening 303 is increased (b in FIG. 10). Then, the SiN film 301 is removed. Through these processes, it is possible to form the opening 306 having the bottom portion in a tapered shape (c in FIG. 10). Further, in b in FIG. 10, by performing alkali chemical treatment using ammonia, or the like, it is also possible to form a bottom portion in a tapered shape by exposing a 111 plane of the silicon single crystal.

Thereafter, by executing the processes described in FIGS. 6 and 7, it is possible to form the element isolation region 12 having a bottom portion in a tapered shape.

### MODIFIED EXAMPLE

While the high-concentration impurity region 13 described above is constituted to have a bottom portion in a tapered shape and have a cross-section in a polygonal shape, the high-concentration impurity region 13 may be configured to have a cross-section in a V-shape.

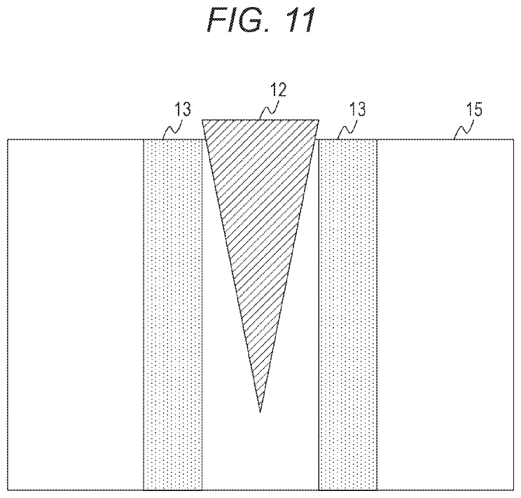

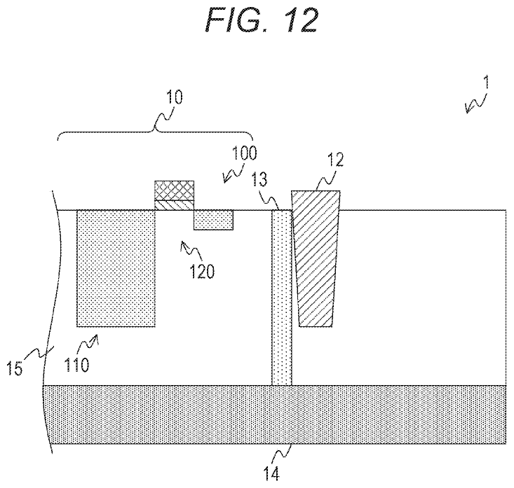

FIG. 11 is a diagram illustrating a configuration example of an element isolation region and a high-concentration impurity region according to a modified example of the second embodiment of the present technology. FIG. 8 is a schematic cross-sectional diagram illustrating a configuration example of the element isolation region and the high-concentration impurity region. The element isolation region 12 in FIG. 11 is configured to have a cross-section in a tapered shape. That is, the element isolation region 12 having a cross-section in a V-shape is formed. In a case where a power supply voltage to be applied to the pixel 100 is low, because it is possible to make withstanding voltage of the element isolation region 12 lower, it is possible to realize the element isolation region 12 having a relatively thin cross-section. In such an element isolation region 12 in a V-shape, a crystal defect is generated by stress concentrating at the bottom portion in a V-shape. By this means, it is possible to suppress generation of a crystal defect which is headed to the pixel 100.

Because the configuration of the imaging element 1 other than this is similar to the configuration of the imaging element 1 described in the first embodiment of the present technology, description will be omitted.

As described above, in the imaging element 1 of the second embodiment of the present technology, by the element isolation region 12 having a bottom portion in a tapered shape being disposed, it is possible to suppress occurrence of a crystal defect which is headed to the pixel 100. By this means, it is possible to further reduce influence of a crystal defect on the semiconductor element region.

### <3. Third Embodiment>

In the imaging element 1 in the above-described first embodiment, the high-concentration impurity region 13 is disposed adjacent to the both sides of the element isolation region 12. In contrast, the imaging element 1 in the third embodiment of the present technology is different from the imaging element 1 in the first embodiment in that the high-concentration impurity region 13 on at least one side is omitted.

### [Configuration of Pixel Array Unit]

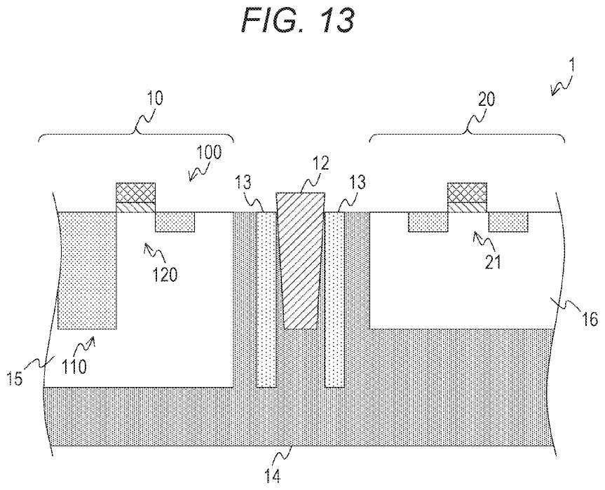

FIG. 12 is a diagram illustrating a configuration example of a pixel array unit according to a third embodiment of the present technology. FIG. 12 is a schematic cross-sectional diagram illustrating a configuration of the element isolation region and the high-concentration impurity region in a similar manner to FIG. 4. FIG. 12 illustrates an example where the pixel array unit 10 is disposed at an end portion of the semiconductor substrate 14. As illustrated in FIG. 12, the element isolation region 12 is disposed between the semiconductor element region such as the pixel 100 and the end portion of the semiconductor substrate 14. By this means, the semiconductor element region is isolated from the end portion of the semiconductor substrate 14. Note that a region between the element isolation region 12 and the end portion of the semiconductor substrate 14 corresponds to a dummy region which is disposed around a region where the pixel 100 is to be disposed (effective pixel region) and which is used as a buffering region.

In this event, the high-concentration impurity region 13 is disposed between the semiconductor element region (pixel 100) and the element isolation region 12, and prevents extension of a crystal defect. Meanwhile, it is possible to omit the high-concentration impurity region 13 between the end portion of the semiconductor substrate 14 and the element isolation region 12. That is because even if a crystal defect extends, there is no influence because the semiconductor element is not disposed in the region. In this manner, when the semiconductor element region is formed in the vicinity of the end portion of the semiconductor substrate 14, it is possible to omit the high-concentration impurity region 13 between the end portion of the semiconductor substrate 14 and the element isolation region 12.

Note that, also in a case where the semiconductor element region in which the element isolation region 12 is disposed is disposed away from other semiconductor element regions, it is possible to omit the high-concentration impurity region 13 between the element isolation region 12 disposed in the vicinity of the semiconductor element region and other semiconductor element regions. That is because there is no influence of a crystal defect in a similar manner to the above-described imaging element 1 because the element isolation region 12 is separated from other semiconductor element regions.

Because the configuration of the imaging element 1 other than this is similar to the configuration of the imaging element 1 described in the first embodiment of the present technology, description will be omitted.

As described above, in the imaging element 1 of the third embodiment of the present technology, by omitting one of the high-concentration impurity regions 13 disposed adjacent to the element isolation region 12, it is possible to simplify the configuration of the imaging element 1.

### <4. Fourth Embodiment>

In the imaging element 1 in the first embodiment described above, the element isolation region 12 is disposed between the pixels 100 formed in the well region 15. In contrast, the imaging element 1 in a fourth embodiment of the present technology is different from the imaging element 1 in the first embodiment in that the element isolation region is disposed between semiconductor element regions formed in different well regions.

### [Configuration of Pixel Array Unit]

FIG. 13 is a diagram illustrating a configuration example of a pixel array unit according to a fourth embodiment of the present technology. FIG. 13 is a diagram illustrating a configuration of a region where the pixel array unit 10 and the vertical driving unit 20 among the imaging element 1 are disposed adjacent to each other. The element isolation region 12 and the high-concentration impurity region 13 in FIG. 13 are different from the element isolation region 12 and the high-concentration impurity region 13 in FIG. 4 in that the element isolation region 12 and the high-concentration impurity region 13 are formed on the semiconductor substrate 14.

In a similar manner to the imaging element 1 described in FIG. 4, the pixel array unit 10 is formed in the well region 15 of the semiconductor substrate 14. In contrast, the vertical driving unit 20 is formed in a well region 16. This well region 16 can be constituted at, for example, a P-type semiconductor. A MOS transistor 21 in FIG. 13 is a MOS transistor which constitutes the vertical driving unit 20, and includes an N-type semiconductor region constituting a source and a drain in a similar manner to the electric charge transferring unit 120, and a gate. As mentioned above, as the pixel array unit 10 and the vertical driving unit 20, semiconductor elements having characteristics different from each other are used. Therefore, also concerning the well regions in which these semiconductor elements are to be formed, these semiconductor element are constituted in the well regions of which impurity concentration, or the like, are different. Further, as the well region 16, there is a case where a well region constituted as an N-type which is a conductive type different from that of the well region 15 is used.

In this manner, when the semiconductor element regions formed in different well regions 15 and 16 are isolated, the element isolation region 12 and the high-concentration impurity region 13 are disposed on the semiconductor substrate 14 between these well regions 15 and 16. The high-concentration impurity regions 13 are respectively disposed on the semiconductor substrate 14 between the element isolation region 12 and the pixel 100, and between the element isolation region 12 and the vertical driving unit 20. Further, the high-concentration impurity region 13 is constituted to have impurity concentration higher than that of the semiconductor substrate 14. By this means, it is possible to prevent a crystal defect which has occurred in the vicinity of the element isolation region 12 from extending to the pixel 100 and the vertical driving unit 20.

Because the configuration of the imaging element 1 other than this is similar to the configuration of the imaging element 1 described in the first embodiment of the present technology, description will be omitted.

As described above, in the imaging element 1 of the fourth embodiment of the present technology, the element isolation region 12 and the high-concentration impurity region 13 are formed on the semiconductor substrate 14 between different well regions. By this means, it is possible to isolate the semiconductor element regions respectively formed in different well regions and reduce influence of an extending crystal defect.

### <5. Application Example of Imaging Element>

The present technology can be applied to various semiconductor elements. For example, the present technology can be applied to the above-described imaging element. A detailed configuration of the imaging element to which the present technology is applied will be described.

### [Configuration of Imaging Element]

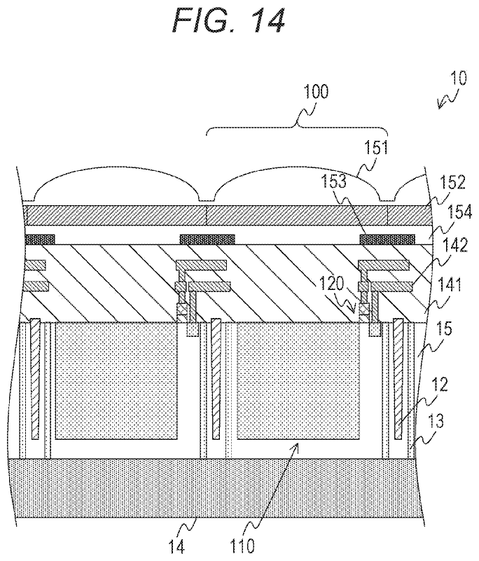

FIG. 14 is a cross-sectional diagram illustrating a first configuration example of an imaging element to which the present technology can be applied. FIG. 14 is a diagram illustrating a detailed configuration example of the pixel array unit 10 described in FIG. 4. The pixel array unit 10 in FIG. 14 further includes an insulating layer 141, a wiring layer 142, a planarizing film 154, a light blocking film 153, a color filter 152 and an on-chip lens 151.

The on-chip lens 151 is a lens which focuses light incident on the pixel 100 and makes the light incident on the photoelectric conversion unit 110.

The color filter 152 is an optical filter which transmits light of a predetermined wavelength among light incident on the pixel 100. As this color filter 152, for example, three types of filters 152 which respectively transmit red light, green light and blue light, can be used.

The planarizing film 154 planarizes a surface of the insulating layer 141. This planarizing film 154 is disposed to make the film thickness of the color filter 152 uniform. The light blocking film 153 is disposed at a boundary of the pixel 100, prevents intrusion of light which penetrates through the color filter 152 of the adjacent pixel 100, and prevents occurrence of color mixture.

The wiring layer 142 electrically connects the semiconductor elements, or the like, formed in the well region 15. FIG. 14 illustrates the wiring layer 142 which is connected to a gate and a drain (electric charge holding unit 121) of the electric charge transferring unit 120 as an example. The wiring layer 142 can be a multi-layer wiring in which a plurality of wirings is laminated. In this case, the wiring layers 142 in different layers can be connected with via plugs. This wiring layer 142 can be constituted with, for example, a metal.

The insulating layer 141 insulates the wiring layer 142. As this insulating layer 141, a transparent insulator, for example, SiO₂ can be used.

The imaging element 1 in FIG. 14 can be manufactured through the following processes. First, a wiring region including the insulating layer 141 and the wiring layer 142 is formed on the surface of the semiconductor substrate 14 on which the element isolation region 12, the high-concentration impurity region 13, or the like, are formed on the basis of the processes described in FIGS. 6 and 7. Then, the light blocking film 153, the planarizing film and the color filter 152 are sequentially laminated on a surface of the wiring region. Finally, the on-chip lens 151 is formed on a surface of the color filter 152. By this means, it is possible to manufacture the imaging element 1.

The imaging element 1 in FIG. 14 corresponds to a surface irradiation type imaging element in which incident light is radiated on the photoelectric conversion unit 110 from a side on which the wiring layer 142 and the insulating layer 141 are formed. In such an imaging element 1, by isolating the pixel 100 with the element isolation region 12 and the high-concentration impurity region 13, it is possible to reduce influence of a crystal defect on the pixel 100.

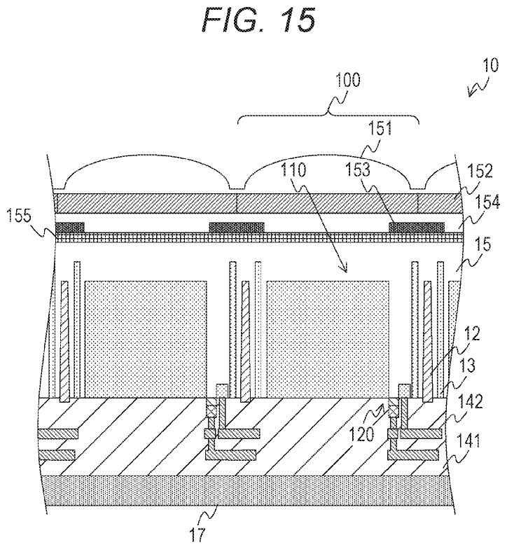

FIG. 15 is a cross-sectional diagram illustrating a second configuration example of an imaging element to which the present technology can be applied. The imaging element 10 in FIG. 15 is different from the imaging element 1 described in FIG. 14 in that incident light is radiated on the photoelectric conversion unit 110 from a side different from a side on which the wiring layer 142 and the insulating layer 141 are formed. The imaging element 1 having such a configuration is referred to as a rear surface irradiation type imaging element. Further, in the imaging element 1 in FIG. 15, a support substrate 17 is disposed adjacent to the insulating layer 141. This support substrate 17 is a substrate which is constituted with a semiconductor substrate, or the like, and which supports the imaging element 1 in the manufacturing process.

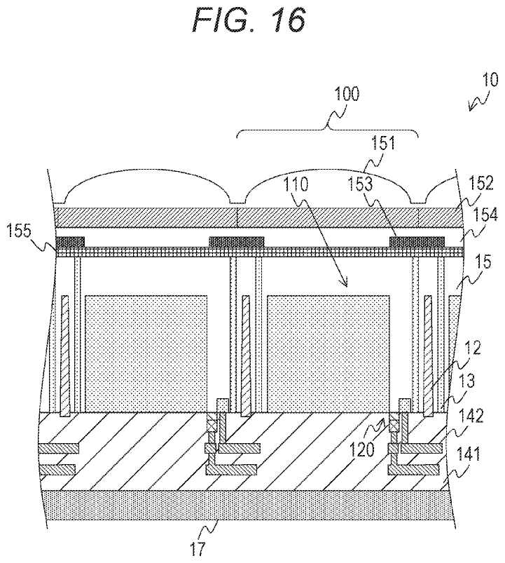

FIG. 16 is a cross-sectional diagram illustrating a third configuration example of an imaging element to which the present technology can be applied. The imaging element 1 in FIG. 16 is different from the imaging element 1 described in FIG. 15 in that the end portion of the high-concentration impurity region 13 is disposed while penetrating through the well region 15.

The imaging element 1 illustrated in FIGS. 15 and 16 can be manufactured through the following processes. The support substrate 17 is adhered adjacent to the wiring region described above in the surface irradiation type imaging element 1, and front/back is reversed. Then, the rear surface is ground while supporting the imaging element 1 with the support substrate 17 to make the semiconductor substrate 14 thinner. Then, the insulating layer 155 is disposed on the semiconductor substrate (well region 15) of which rear surface has been ground. Thereafter, by sequentially laminating the light blocking film 153, the planarizing film and the color filter 152 and forming the on-chip lens 151, it is possible to form the rear surface irradiation type imaging element 1.

Also in these rear surface irradiation type imaging elements 1, by disposing the element isolation region 12 and the high-concentration impurity region 13 in a similar manner to the surface irradiation type imaging element 1 described above, it is possible to reduce influence of a crystal defect on the pixel 100.

### <6. Application Example to Camera>

The present technology is able to be applied to various products. For example, the present technology may be realized as an imaging element mounted on an imaging device such as a camera.

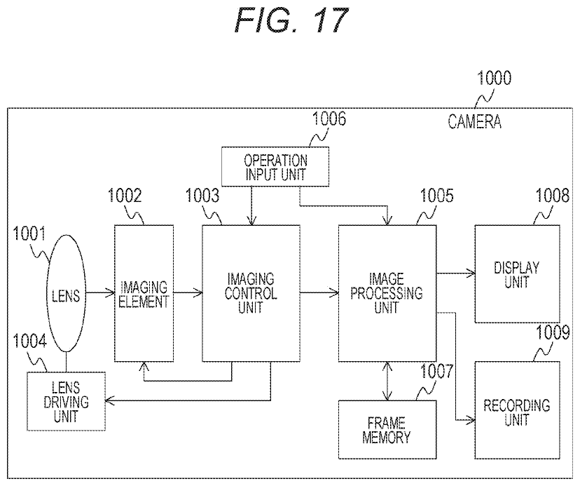

FIG. 17 is a block diagram illustrating a schematic configuration example of a camera that is an example of the imaging device to which the present technology is able to be applied. The camera 1000 in FIG. 17 includes a lens 1001, an imaging element 1002, an imaging control unit 1003, a lens driving unit 1004, an image processing unit 1005, an operation input unit 1006, a frame memory 1007, a display section 1008, and a recording unit 1009.

The lens 1001 is an imaging lens of the camera 1000. The lens 1001 condenses light from a subject and causes the light to enter the imaging element 1002 that will be described later to form an image of the subject.

The imaging element 1002 is a semiconductor element that images the light from the subject condensed by the lens 1001. The imaging element 1002 generates an analog image signal according to emitted light, converts the analog image signal into a digital image signal, and outputs the digital image signal.

The imaging control unit 1003 controls imaging in the imaging element 1002. The imaging control unit 1003 controls the imaging element 1002 by generating a control signal and outputting the control signal to the imaging element 1002. Further, the imaging control unit 1003 can perform autofocus at the camera 1000 on the basis of the image signal output from the imaging element 1002. Here, autofocus is a system which detects and automatically adjusts a focus position of the lens 1001. As this autofocus, it is possible to use a scheme in which an image plane phase difference is detected with phase difference pixels disposed in the imaging element 1002, and a focus position is detected (image plane phase difference autofocus). Further, it is also possible to apply a scheme in which a position at which contrast of an image becomes the highest is detected as the focus position (contrast autofocus). The imaging control unit 1003 performs autofocus by adjusting the position of the lens 1001 via the lens driving unit 1004 on the basis of the detected focus position. Note that, for example, the imaging control unit 1003 is able to include a digital signal processor (DSP) on which firmware is mounted.

The lens driving unit 1004 drives the lens 1001 on the basis of control by the imaging control unit 1003. This lens driving unit 1004 can drive the lens 1001 by changing the position of the lens 1001 using a built-in motor.

The image processing unit 1005 processes the image signal generated by the imaging element 1002. The process includes, for example, a demosaic for generating an image signal of insufficient color among image signals corresponding to red, green and blue for each pixel, noise reduction for removing noise of an image signal, encoding of an image signal, and the like. Note that the image processing unit 1005 is able to include, for example, a microcomputer on which firmware is mounted.

The operation input unit 1006 receives an operation input from a user of the camera 1000. For example, a push button or a touch panel is able to be used as the operation input unit 1006. The operation input received by the operation input unit 1006 is transferred to the imaging control unit 1003 or the image processing unit 1005. Thereafter, a process according to the operation input, for example, a process such as imaging of the subject is started.

The frame memory 1007 is a memory that stores a frame that is an image signal for one screen. The frame memory 1007 is controlled by the image processing unit 1005, and holds a frame in a process of image processing.

The display section 1008 displays the image processed by the image processing unit 1005. For example, a liquid crystal panel is able to be used for the display section 1008.

The recording unit 1009 records the image processed by the image processing unit 1005. For example, a memory card or a hard disk is able to be used for the recording unit 1009.

The camera to which the present technology is able to be applied has been described above. The present technology is able to be applied to the imaging element 1002 in the configuration described above. Specifically, the imaging device 1 described with reference to FIG. 1 is able to be applied to the imaging element 1002. By the imaging device 1 being applied to the imaging element 1002, it is possible to reduce a dark current as a result of influence of a crystal defect on the semiconductor substrate being reduced, and it is possible to prevent degradation of image quality of the image generated by the camera 1000.

Note that, here, the camera has been described as an example, but the technology according to the present technology may be applied to other apparatuses, for example, a surveillance apparatus and the like.

### <7. Application Example to Endoscopic Surgery System>

A technology (present technology) according to an embodiment of the present disclosure can be applied to various products. For example, the technology according to an embodiment of the present disclosure may be applied to an endoscopic surgery system.

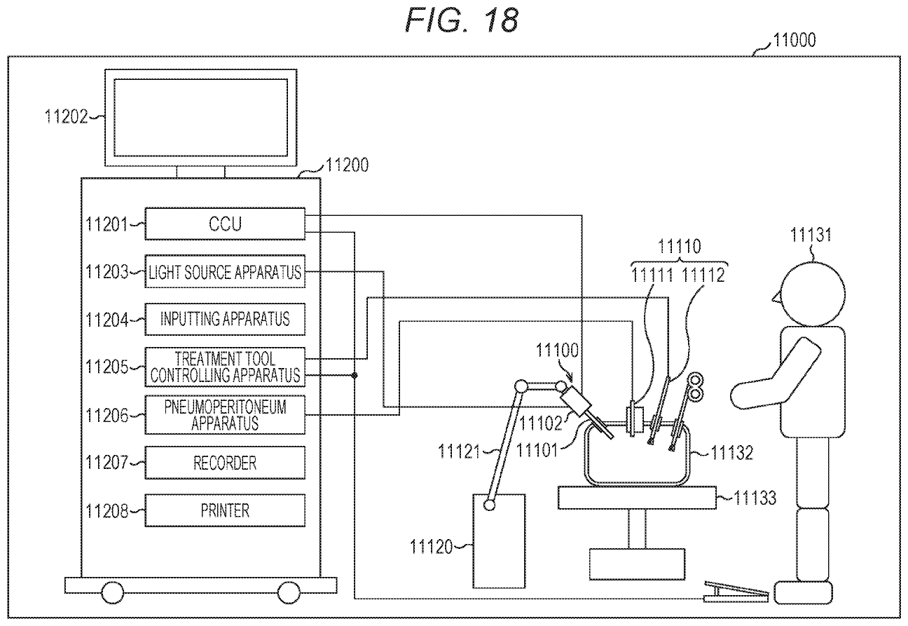

FIG. 18 is a view depicting an example of a schematic configuration of an endoscopic surgery system to which the technology according to an embodiment of the present disclosure (present technology) can be applied.

In 10, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which is included as a rigid endoscope having the lens barrel 11101 of the hard type. However, the endoscope 11100 may otherwise be included as a flexible endoscope having the lens barrel of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an imaging element are provided in the inside of the camera head 11102 such that reflected light (observation light) from the observation target is condensed on the imaging element by the optical system. The observation light is photo-electrically converted by the imaging element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region and the like to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or the like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the imaging elements of the camera head 11102 are controlled in synchronism with the irradiation timings, it is also possible to time-divisionally capture images corresponding to respective R, G and B. According to the method just described, a color image can be obtained even if a color filter is not provided for the imaging element.

Further, the light source apparatus 11203 may be controlled such that the intensity of light to be outputted is changed for each predetermined time. By controlling driving of the imaging element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrower wavelength band in comparison with irradiation light upon ordinary observation (namely, white light), so-called narrow band light observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue, for example. The light source apparatus 11203 can be configured to supply such narrow-band light and/or excitation light suitable for special light observation as described above.

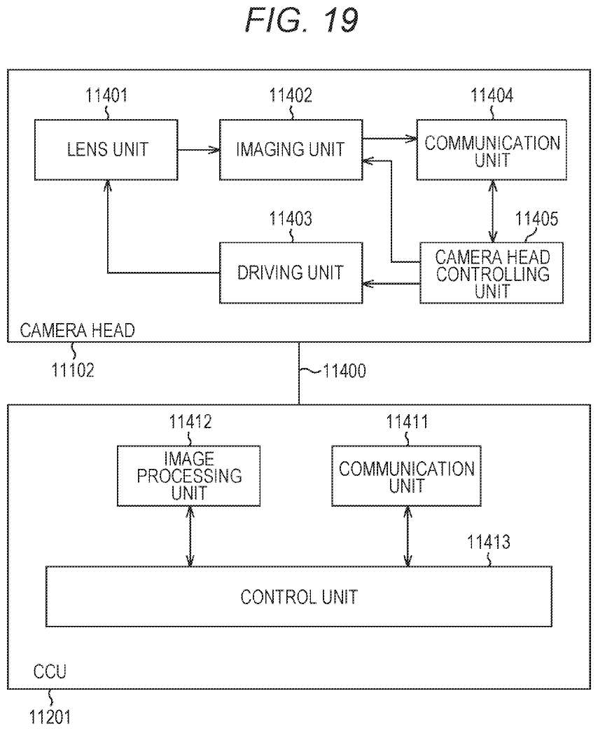

FIG. 19 is a block diagram depicting an example of a functional configuration of the camera head 11102 and the CCU 11201 depicted in FIG. 18.

The camera head 11102 includes a lens unit 11401, an imaging unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The imaging unit 11402 includes imaging elements. The number of imaging elements which is included by the imaging unit 11402 may be one (so-called single-plate type) or a plural number (so-called multi-plate type). Where the imaging unit 11402 is configured as that of the multi-plate type, for example, image signals corresponding to respective R, G and B are generated by the imaging elements, and the image signals may be synthesized to obtain a color image. The imaging unit 11402 may also be configured so as to have a pair of imaging elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, in a case where the imaging unit 11402 is configured as that of multi-plate type, a plurality of systems of lens units 11401 is provided corresponding to the individual imaging elements.

Further, the imaging unit 11402 may not necessarily be provided on the camera head 11102. For example, the imaging unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the imaging unit 11402 can be adjusted suitably.

The communication unit 11404 includes a communication apparatus for transmitting and receiving various kinds of information to and from the CCU 11201. The communication unit 11404 transmits an image signal acquired from the imaging unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to imaging conditions such as, for example, information by which a frame rate of a picked up image is designated, information by which an exposure value upon image picking up is designated and/or information by which a magnification and a focal point of a picked up image are designated.

It is to be noted that the image pickup conditions such as the frame rate, exposure value, magnification or focal point may be appropriately designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above description describes an example of an endoscopic surgery system to which the technology according to the present disclosure can be applied. The technology according to the present disclosure can be applied to the imaging unit 11402 of the camera head 11102 of the constituent elements described above. Specifically, the imaging device 1 in FIG. 1 can be applied to the imaging unit 10402. When the technology according to the present disclosure is applied to the imaging unit 10402, it is possible to prevent the degradation of image quality, and thus a surgical region can be comprehended with certainty by the surgeon.

Note that, here, an endoscopic surgery system is described as an example, but the technology according to the present disclosure may be applied to other systems such as a microsurgery system, for example.

### <8. Application Example to Mobile Object>

A technology (present technology) according to an embodiment of the present disclosure can be applied to various products. For example, the technology according to the present disclosure may also be realized as a device mounted in a mobile object of any type such as automobile, electric vehicle, hybrid electric vehicle, motorcycle, bicycle, personal mobility, airplane, drone, ship, or robot.

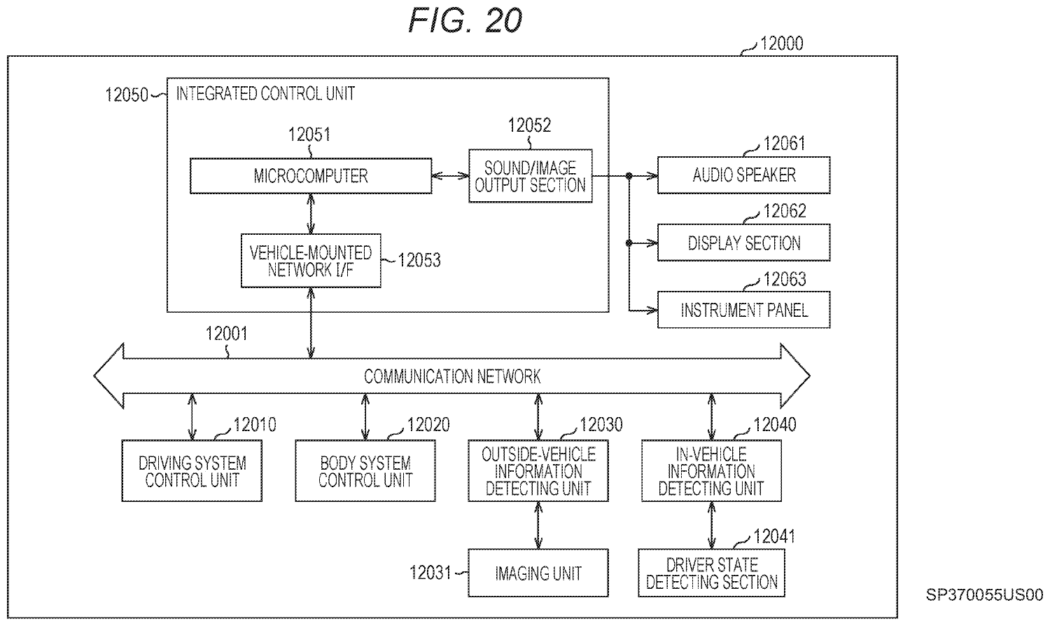

FIG. 20 is a block diagram depicting an example of schematic configuration of a vehicle control system as an example of a mobile object control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging unit 12031. The outside-vehicle information detecting unit 12030 makes the imaging unit 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging unit 12031 is an optical sensor that receives light, and which outputs an electric signal corresponding to a received light amount of the light. The imaging unit 12031 can output the electric signal as an image, or can output the electric signal as information about a measured distance. In addition, the light received by the imaging unit 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the surroundings of the vehicle which is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound or an image to an output device capable of visually or auditorily notifying an occupant of the vehicle or the outside of the vehicle of information. In the example of FIG. 20, an audio speaker 12061, a display section 12062, and an instrument panel 12063 are illustrated as the output device. The display section 12062 may, for example, include at least one of an on-board display and a head-up display.

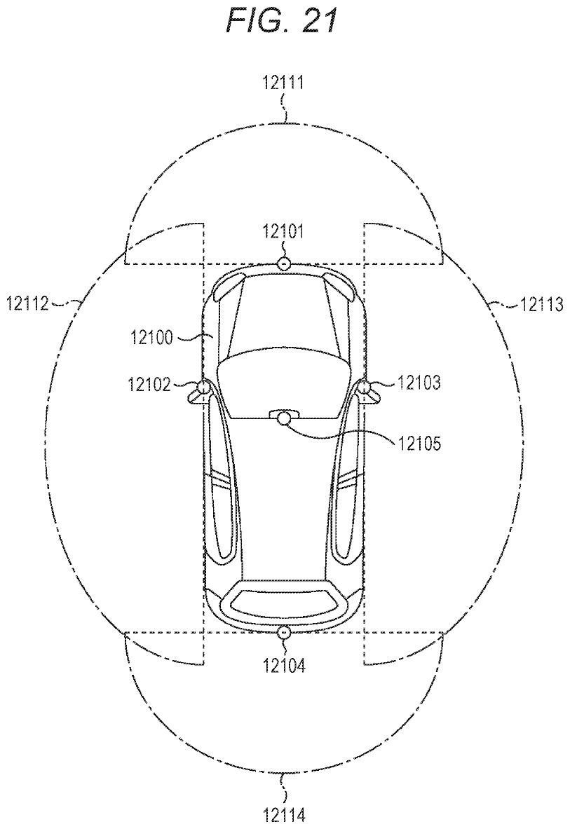

FIG. 21 is a diagram depicting an example of the installation position of the imaging unit 12031.

In FIG. 21, the vehicle 12100 includes imaging units 12101, 12102, 12103, 12104, and 12105 as the imaging unit 12031.

The imaging units 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging unit 12101 provided to the front nose and the imaging unit 12105 provided to the upper portion of the windshield within the interior of the vehicle obtain mainly an image of the front of the vehicle 12100. The imaging units 12102 and 12103 provided to the sideview mirrors obtain mainly an image of the sides of the vehicle 12100. The imaging unit 12104 provided to the rear bumper or the back door obtains mainly an image of the rear of the vehicle 12100. The images of the front obtained by the imaging units 12101 and 12105 are used mainly to detect a preceding vehicle, a pedestrian, an obstacle, a signal, a traffic sign, a lane, or the like.

Incidentally, FIG. 21 depicts an example of imaging ranges of the imaging units 12101 to 12104. An imaging range 12111 represents the imaging range of the imaging unit 12101 provided to the front nose. Imaging ranges 12112 and 12113 respectively represent the imaging ranges of the imaging units 12102 and 12103 provided to the sideview mirrors. An imaging range 12114 represents the imaging range of the imaging unit 12104 provided to the rear bumper or the back door. A bird's-eye image of the vehicle 12100 as viewed from above is obtained by superimposing image data imaged by the imaging units 12101 to 12104, for example.

At least one of the imaging units 12101 to 12104 may have a function of obtaining distance information. For example, at least one of the imaging units 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging units 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging units 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging units 12101 to 12104 may be an infrared camera that detects infrared rays. The microcomputer 12051 can, for example, recognize a pedestrian by determining whether or not there is a pedestrian in imaged images of the imaging units 12101 to 12104. Such recognition of a pedestrian is, for example, performed by a procedure of extracting characteristic points in the imaged images of the imaging units 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging units 12101 to 12104, and thus recognizes the pedestrian, the sound/image output section 12052 controls the display section 12062 so that a square contour line for emphasis is displayed so as to be superimposed on the recognized pedestrian. In addition, the sound/image output section 12052 may also control the display section 12062 so that an icon or the like representing the pedestrian is displayed at a desired position.

The above description describes an example of a vehicle control system to which the technology according to the present disclosure can be applied. The technology according to the present disclosure may be applied to the imaging unit 12031 or the like among the configurations described above. Specifically, the imaging device 1 in FIG. 1 can be applied to the imaging units 12031 and 12101 to 12105. By applying the technology according to the present disclosure to the imaging unit 12031 or the like, it is possible to prevent the degradation of image quality, and thus it is possible to reduce fatigue of the driver.

Finally, the description of each of the embodiments described above is an example of the present technology, and the present technology is not limited to the embodiments described above. Therefore, of course, various modifications are able to be made according to the design or the like as long as the modifications do not depart from the technical spirit according to the present technology, even if the modifications are other than each of the embodiments described above.

Additionally, the present technology may also be configured as below.

(1) A semiconductor device including:
a semiconductor element region disposed on a surface of a semiconductor substrate;
an element isolation region which is formed in a predetermined depth from the surface of the semiconductor substrate and which isolates the semiconductor element region; and
a high-concentration impurity region in which is constituted to have impurity concentration higher than impurity concentration of the semiconductor substrate, which is disposed between the semiconductor element region and the element isolation region, and which is not disposed below the element isolation region.

(2) The semiconductor device according to (1), in which the element isolation region is constituted with an insulator.

(3) The semiconductor device according to (1) or (2), in which the high-concentration impurity region is formed in a region deeper than a bottom portion of the element isolation region from a surface of the semiconductor element.

(4) The semiconductor device according to any one of (1) to (3), in which the element isolation region includes a bottom portion having a cross-section in a tapered shape of which width becomes narrower as a depth from the surface of the semiconductor substrate becomes deeper.

(5) The semiconductor device according to (4), in which the element isolation region has an angle based on a cross-section at a portion which transitions to the bottom portion in the tapered shape, greater than an angle based on a cross-section at a top of the tapered shape.

(6) A manufacturing method of a semiconductor device, including:
a step of forming a semiconductor element region on a surface of a semiconductor substrate;
a step of forming an element isolation region which isolates the semiconductor element region in a predetermined depth from the surface of the semiconductor substrate; and
a step of forming a high-concentration impurity region having impurity concentration higher than impurity concentration of the semiconductor substrate, between the semiconductor element region and the element isolation region, while not forming the high-concentration impurity region below the isolation region.

### REFERENCE SIGNS LIST

1, 1002 Imaging element

10 Pixel array unit

12 Element isolation region

13 High-concentration impurity region

14 Semiconductor substrate

15, 16 Well region

20 Vertical driving unit

30 Column signal processing unit

40 Control unit

100 Pixel

10402, 12031, 12101 to 12105 imaging unit

1. A semiconductor device comprising:
a semiconductor element region disposed on a surface of a semiconductor substrate;
an element isolation region which is formed in a predetermined depth from the surface of the semiconductor substrate and which isolates the semiconductor element region; and
a high-concentration impurity region which is constituted to have impurity concentration higher than impurity concentration of the semiconductor substrate, which is disposed between the semiconductor element region and the element isolation region, and which is not disposed below the element isolation region.

2. The semiconductor device according to claim 1, wherein the element isolation region is constituted with an insulator.

3. The semiconductor device according to claim 1, wherein the high-concentration impurity region is formed in a region deeper than a bottom portion of the element isolation region from a surface of the semiconductor element.

4. The semiconductor device according to claim 1, wherein the element isolation region includes a bottom portion having a cross-section in a tapered shape of which width becomes narrower as a depth from the surface of the semiconductor substrate becomes deeper.

5. The semiconductor device according to claim 4, wherein the element isolation region has an angle based on a cross-section at a portion which transitions to the bottom portion in the tapered shape, greater than an angle based on a cross-section at a top of the tapered shape.

6. A manufacturing method of a semiconductor device, comprising:
a step of forming a semiconductor element region on a surface of a semiconductor substrate;
a step of forming an element isolation region which isolates the semiconductor element region in a predetermined depth from the surface of the semiconductor substrate; and
a step of forming a high-concentration impurity region having impurity concentration higher than impurity concentration of the semiconductor substrate, between the semiconductor element region and the element isolation region, while not forming the high-concentration impurity region below the element isolation region.
